(19) United States
(12) Patent Application Publication
(10) Pub. No.: US 2025/0044685 A1
(43) Pub. Date: Feb. 6, 2025

(54) SEMICONDUCTOR PHOTORESIST COMPOSITION AND METHOD OF FORMING PATTERNS USING THE COMPOSITION

(71) Applicant: SAMSUNG SDI CO., LTD., Yongin-si (KR)

(72) Inventors: Changsoo WOO, Suwon-si (KR); Seol Hee LIM, Suwon-si (KR); Minyoung LEE, Suwon-si (KR); Jimin KIM, Suwon-si (KR)

(21) Appl. No.: 18/755,491

(22) Filed: Jun. 26, 2024

(30) Foreign Application Priority Data
Aug. 4, 2023 (KR) 10-2023-0102400

(51) Int. Cl. G03F 7/004; G03F 1/80; G03F 7/11; G03F 7/16; G03F 7/20

(52) U.S. Cl. CPC G03F 7/0042; G03F 1/80; G03F 7/11; G03F 7/16; G03F 7/2004

(57) ABSTRACT

A semiconductor photoresist composition includes an organometallic compound represented by Chemical Formula 1 and a solvent. A method of forming (or providing) patterns utilizing the same is provided.

(R¹)ₙ₁-M-[(X)—R²]ₘ₁ [Chemical Formula 1]

### CROSS-REFERENCE TO RELATED APPLICATION

This application claims priority to and the benefit of Korean Patent Application No. 10-2023-0102400, filed in the Korean Intellectual Property Office on Aug. 4, 2023, the entire content of which is incorporated herein by reference.

### BACKGROUND

### 1. Field

This disclosure relates to a semiconductor photoresist composition and a method of forming (or providing) patterns utilizing the same.

### 2. Description of the Related Art

Extreme ultraviolet (EUV) lithography has been recognized as the technology (e.g., one essential technology) for manufacturing a next generation semiconductor device. The EUV lithography is a pattern-forming (or providing) technology utilizing an EUV ray having a wavelength of about 13.5 nanometer (nm) as an exposure light source. Utilizing the EUV lithography, an extremely fine pattern (e.g., less than or equal to about 20 nm) may be formed in an exposure process during a manufacturing process of a semiconductor device.

The extreme ultraviolet (EUV) lithography is realized through development of compatible photoresists, which can be performed at a spatial resolution of less than or equal to about 16 nm. Currently, efforts to address insufficient specifications of traditional chemically amplified (CA) photoresists, such as related to resolution, photospeed, and/or feature roughness (or also referred to as a line edge roughness or LER) for the next generation device, are being pursued (made).

An intrinsic image blurring due to an acid catalyzed reaction in these polymer-type or kind photoresists limits a resolution in small feature sizes, which has been known in electron beam (e-beam) lithography for a long time. The chemically amplified (CA) photoresists are designed for relatively high sensitivity, but because their typical elemental makeups reduce light absorbance of the photoresists at a wavelength of about 13.5 nm and thus decrease their sensitivity, the chemically amplified (CA) photoresists may partially have more difficulties under an EUV exposure.

In addition, the CA photoresists may have difficulties in the small feature sizes due to roughness issues, and line edge roughness (LER) of the CA photoresists turns out to be increased in experiments, as a photospeed is decreased partially due to an essence (e.g., inherent characteristics) of acid catalyst processes. Accordingly, a novel relatively high-performance photoresist is desired or required in the semiconductor industry because of these defects and problems of the CA photoresists.

In order to overcome the aforementioned drawbacks of the chemically amplified (CA) organic photosensitive composition, an inorganic photosensitive composition has been researched. The inorganic photosensitive composition, having resistance against removal by a developer composition due to chemical modification through nonchemical amplification mechanism, is mainly utilized for negative tone patterning. The inorganic composition contains an inorganic element having a higher EUV absorption rate than hydrocarbons and thus may secure suitable sensitivity through the nonchemical amplification mechanism. In addition, the inorganic composition is less sensitive to a stochastic effect and thus may have relatively low line edge roughness and the small number of defects.

Inorganic photoresists based on peroxopolyacids of tungsten mixed with tungsten, niobium, titanium, and/or tantalum have been reported as radiation sensitive materials for patterning (See also, e.g., U.S. Pat. No. 5,061,599; and H. Okamoto, T. Iwayanagi, K. Mochiji, H. Umezaki, T. Kudo, Applied Physics Letters, 49(5), 298-300, 1986, the entire content of each of which is incorporated herein by reference).

These materials are effective for patterning large pitches for bilayer configuration as far ultraviolet (deep UV), X-ray, and electron beam sources. More recently, suitable performance has been obtained when cationic hafnium metal oxide sulfate (HfSOx) materials along with a peroxo complexing agent have been utilized to image a 15 nm half-pitch (HP) through projection EUV exposure. (See also, e.g., US 2011-0045406; and J. K. Stowers, A. Telecky, M. Kocsis, B. L. Clark, D. A. Keszler, A. Grenville, C. N. Anderson, P. P. Naulleau, Proc. SPIE, 7969, 796915, 2011, the entire content of each of which is incorporated herein by reference). This system/procedure exhibits better performance as a non-CA photoresist and has a practicable photospeed close to a requirement for an EUV photoresist. However, the hafnium metal oxide sulfate material having the peroxo complexing agent has a few practical drawbacks. First, these materials are coated in a mixture of corrosive sulfuric acid/hydrogen peroxide and may have insufficient shelf-life stability. Second, as a composite mixture, a structural change thereof for performance improvement is not easy. Third, development is (e.g., should be) performed in a tetramethylammonium hydroxide (TMAH) solution at a relatively high (e.g., extremely high) concentration of about 25 wt % and/or the like.

### SUMMARY

Aspects according to some embodiments are directed toward a semiconductor photoresist composition that exhibits excellent or suitable sensitivity and improved stability.

Aspects according to some embodiments are directed toward a method of forming (or providing) patterns utilizing the semiconductor photoresist composition.

Additional aspects will be set forth in part in the description which follows and, in part, will be apparent from the description, or may be learned by practice of the presented embodiments of the disclosure.

Recently, active research has been conducted on molecules (e.g., materials) containing tin, which have excellent or suitable absorption of extreme ultraviolet rays. Among them, as for an organotin polymer, the alkyl ligands are dissociated by light absorption or secondary electrons produced thereby, and are crosslinked with adjacent chains through oxo bonds and thus enable the negative tone patterning which may not be removed by an organic developer. This organotin polymer exhibits greatly improved sensitivity as well as maintains a suitable resolution and line edge roughness, but the patterning characteristics need to be additionally improved for commercial availability.

According to some embodiments, a semiconductor photoresist composition includes an organometallic compound represented by Chemical Formula 1 and a solvent.

(R¹)ₙ₁-M-[(X)—R²]ₘ₁ [Chemical Formula 1]

In Chemical Formula 1,
M is a tetravalent metal, a pentavalent metal, or a hexavalent metal,
R¹ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or L^{a}-O—R^{a} (wherein L^{a} is a substituted or unsubstituted C1 to C20 alkylene group and R^{a} is a substituted or unsubstituted C1 to C20 alkyl group),
R² is a tert-butyl group, a benzoyl group, a pivaloyl group, an acetyl group, a tert-butyldiphenylsilyl group, a tert-butyldimethylsilyl group, an allyl group, a tetrahydropyranyl group, a methoxymethyl group, a benzyl ether group, a tert-butyl ether group, a p-toluenesulfonyl group, a 2-phenylethenyl group, a benzyl group, a trifluoromethyl group, a benzyl ester group, a tert-butyl ester group, a 9-fluorenylmethyl group, or a triphenylmethyl group,
X is O-[L¹-O]ₙ₂ (wherein L¹ is a substituted or unsubstituted C1 to C20 alkylene group, a substituted or unsubstituted C6 to C30 arylene group, or a (e.g., any suitable) combination thereof, and n2 is an integer selected from 0 to 10), O—C(O)—[L²-C(O)O]ₙ₃ (wherein L² is a substituted or unsubstituted C1 to C20 alkylene group, a substituted or unsubstituted C6 to C30 arylene group, or a (e.g., any suitable) combination thereof, and n3 is an integer selected from 0 to 10), N(R³)—[L³-N(R⁴)]ₙ₄ (wherein L³ is a substituted or unsubstituted C1 to C20 alkylene group, a substituted or unsubstituted C6 to C30 arylene group, or a (e.g., any suitable) combination thereof, R³ and R⁴ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof, and n4 is an integer selected from 0 to 10), N(R⁵)C(O)—[L⁴-N(R⁶)C(O)]ₙ₅ (wherein L⁴ is a substituted or unsubstituted C1 to C20 alkylene group, a substituted or unsubstituted C6 to C30 arylene group, or a (e.g., any suitable) combination thereof, R⁵ and R⁶ are each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof, and n5 is an integer selected from 0 to 10), or N(R⁷)C—N(R⁸)-[L⁵-N(R⁹)C—N(R¹⁰)]ₙ₆ (wherein L⁵ is a substituted or unsubstituted C1 to C20 alkylene group, or a substituted or unsubstituted C6 to C30 arylene group, or a (e.g., any suitable) combination thereof, R⁷ to R¹⁰ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof, and n6 is an integer selected from 0 to 10),
n1 and m1 may each independently be an integer selected from 1 to 5, and

4≤n1+m1≤6.

In some embodiments, M may be one selected from among Sn, Sb, I, Te, In, Ag, Ni, Bi, and Po.

In some embodiments, M may be Sn.

In some embodiments, R¹ may be a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or L^{a}-O—R^{a} (wherein L^{a} may be a substituted or unsubstituted C1 to C10 alkylene group, and R^{a} may be a substituted or unsubstituted C1 to C10 alkyl group), and
X may be O, O—C(O), N(R³) (wherein R³ may be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a (e.g., any suitable) combination thereof), N(R⁵)C(O) (wherein R⁵ may be a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a (e.g., any suitable) combination thereof), or N(R⁷)C—N(R⁸) (wherein, R⁷ and R⁸ may each independently be a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a (e.g., any suitable) combination thereof).

In some embodiments, R¹ may be a methyl group, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, a formyl group, an acetyl group, a propanoyl group, a butanoyl group, a pentanoyl group, an ethoxy group, a propoxy group, or a (e.g., any suitable) combination thereof.

In some embodiments, R³ to R¹⁰ may each independently be hydrogen, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a (e.g., any suitable) combination thereof.

In some embodiments, the organometallic compound may be one selected from among compounds listed in Group 1.

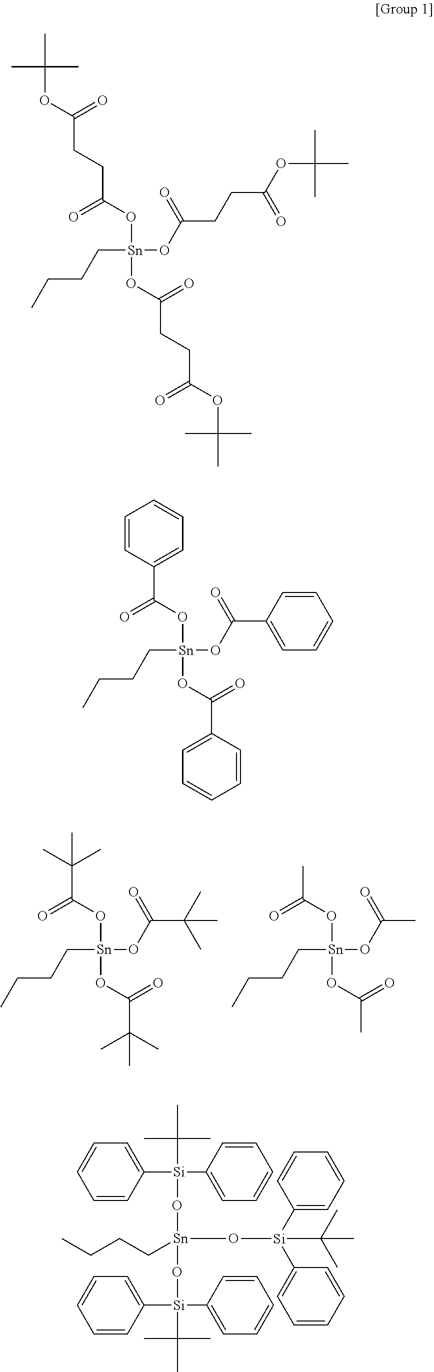

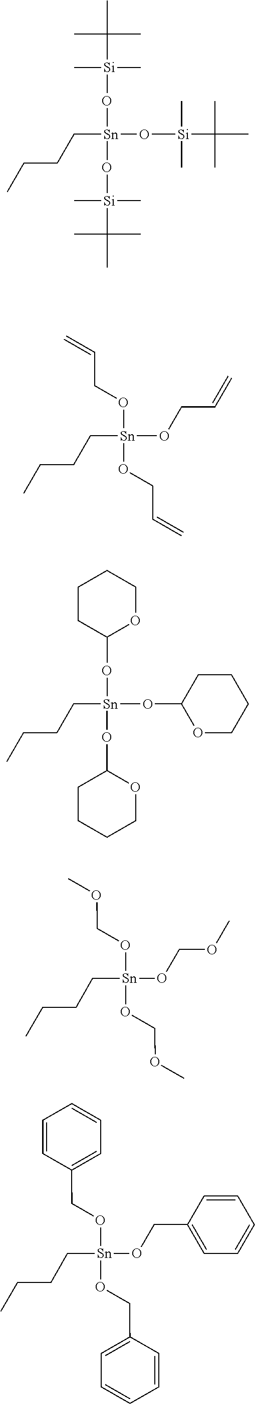

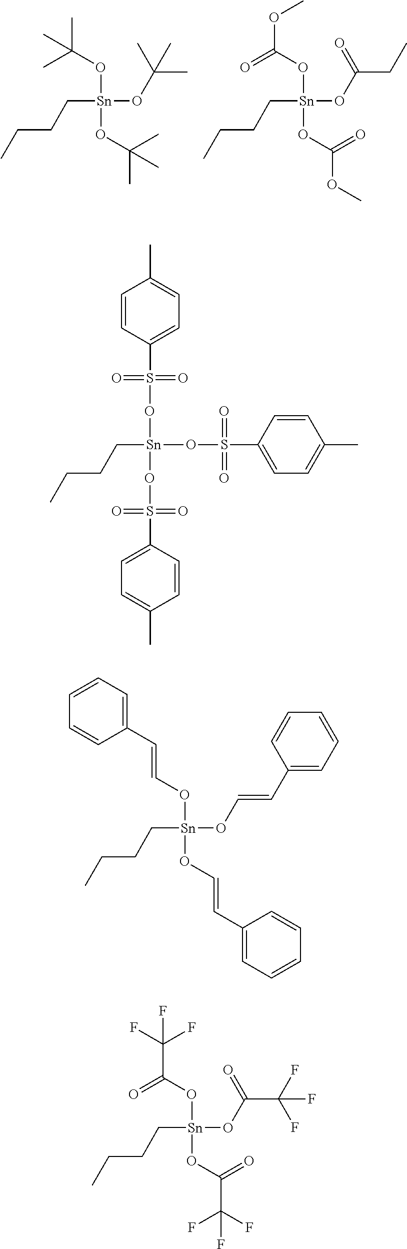

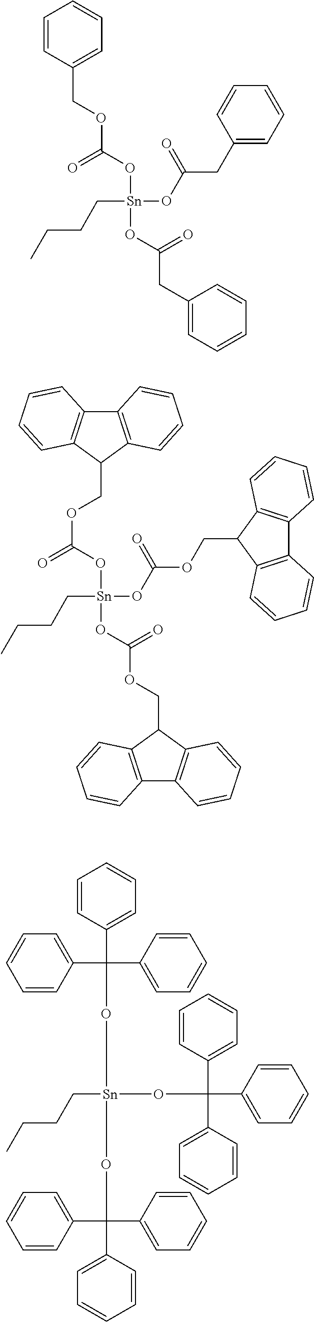 [SMILES: CCC[CH2][Sn]([O]C(=O)Cc1ccccc1)([O]C(=O)Cc1ccccc1)[O]C(=O)OCc1ccccc1 ; CCC[CH2][Sn]([O]C(=O)OCC1c2ccccc2-c2ccccc21)([O]C(=O)OCC1c2ccccc2-c2ccccc21)[O]C(=O)OCC1c2ccccc2-c2ccccc21 ; CCC[CH2][Sn]([O]C(c1ccccc1)(c1ccccc1)c1ccccc1)([O]C(c1ccccc1)(c1ccccc1)c1ccccc1)[O]C(c1ccccc1)(c1ccccc1)c1ccccc1]

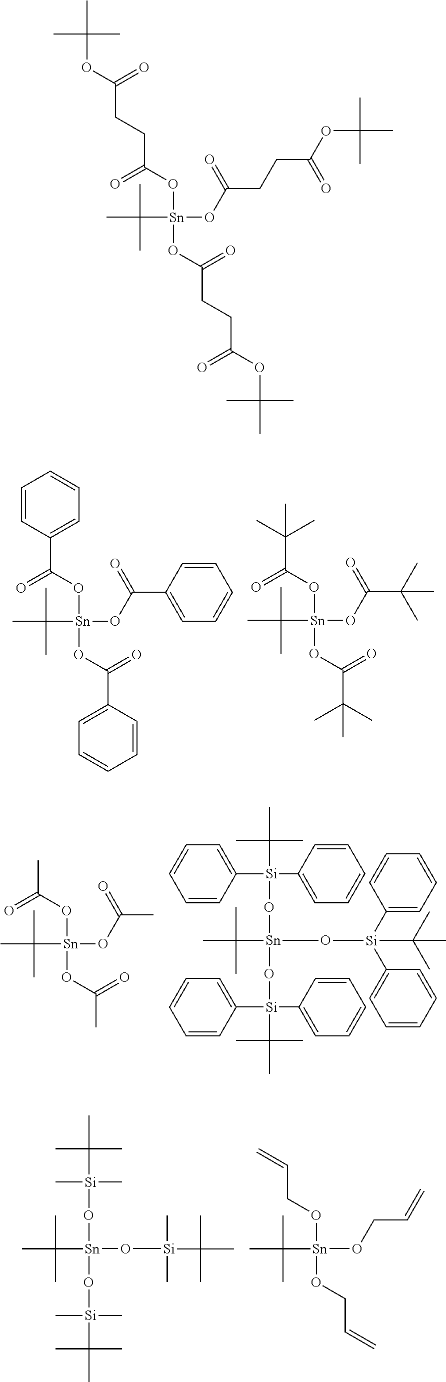

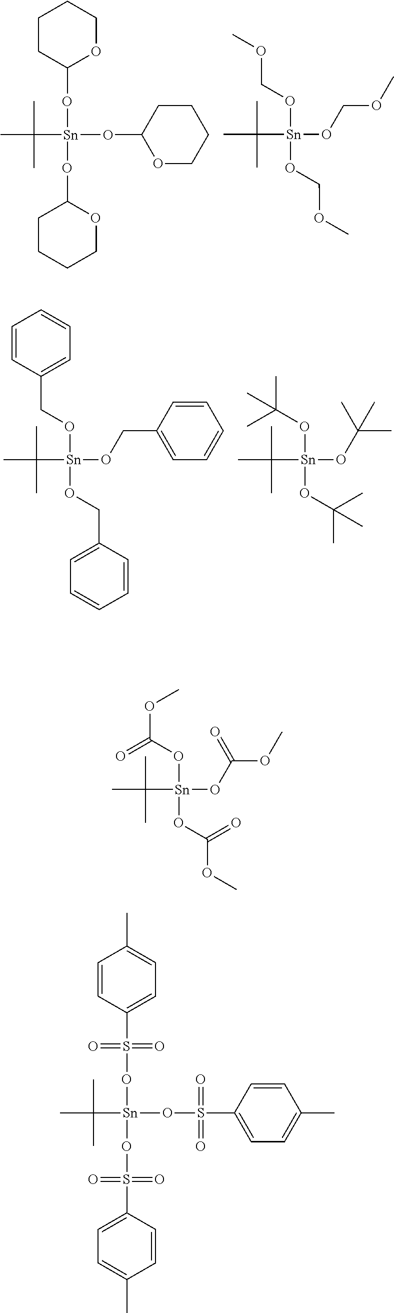

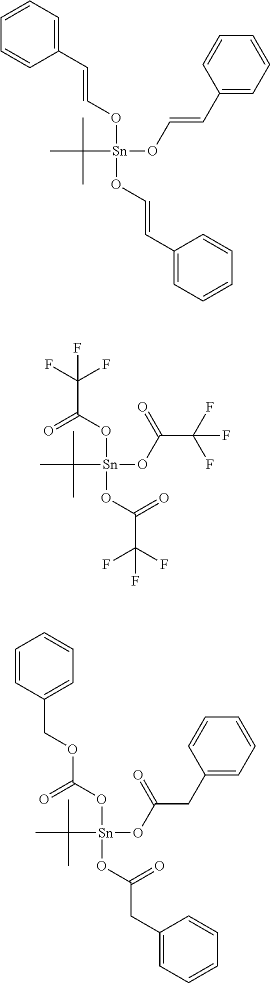 [SMILES: C[C](C)(C)[Sn]([O]/C=C/c1ccccc1)([O]/C=C/c1ccccc1)[O]/C=C/c1ccccc1 ; C[C](C)(C)[Sn]([O]C(=O)C(F)(F)F)([O]C(=O)C(F)(F)F)[O]C(=O)C(F)(F)F ; C[C](C)(C)[Sn]([O]C(=O)Cc1ccccc1)([O]C(=O)Cc1ccccc1)[O]C(=O)OCc1ccccc1]

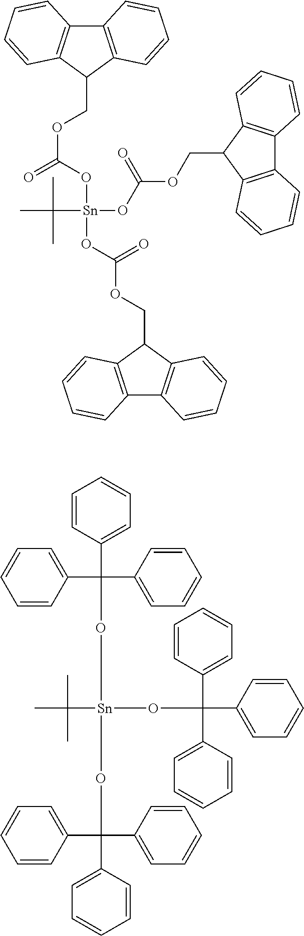 [SMILES: C[C](C)(C)[Sn]([O]C(=O)OCC1c2ccccc2-c2ccccc21)([O]C(=O)OCC1c2ccccc2-c2ccccc21)[O]C(=O)OCC1c2ccccc2-c2ccccc21 ; C[C](C)(C)[Sn]([O]C(c1ccccc1)(c1ccccc1)c1ccccc1)([O]C(c1ccccc1)(c1ccccc1)c1ccccc1)[O]C(c1ccccc1)(c1ccccc1)c1ccccc1]

In some embodiments, the organometallic compound may be included in an amount of about 1 wt % to about 30 wt % based on 100 wt % of the semiconductor photoresist composition.

In some embodiments, the semiconductor photoresist composition may further include an additive selected from among a surfactant, a crosslinking agent, a leveling agent, and a (e.g., any suitable) combination thereof.

In some embodiments, a method of forming (or providing) patterns includes forming (or providing) an etching-objective layer on a substrate, coating the semiconductor photoresist composition on the etching-objective layer to form (or provide) a photoresist layer, patterning the photoresist layer to form (or provide) a photoresist pattern, and etching the etching-objective layer utilizing the photoresist pattern as an etching mask.

In some embodiments, the photoresist pattern may be formed utilizing light having a wavelength of about 5 nm to about 150 nm.

In some embodiments, the method of forming (or providing) patterns may further include providing a resist underlayer between the substrate and the photoresist layer.

In some embodiments, the photoresist pattern may have a width of about 5 nm to about 100 nm.

The semiconductor photoresist composition according to some embodiments may provide a photoresist pattern with improved storage stability, moisture stability, and sensitivity.

### BRIEF DESCRIPTION OF THE DRAWINGS

The accompanying drawings are included to provide a further understanding of the present disclosure and are incorporated in and constitute a part of this specification. The drawings illustrate embodiments of the present disclosure and, together with the description, serve to explain principles of the present disclosure. In the drawings:

FIGS. 1-5 are cross-sectional views for explaining a method of forming (or providing) patterns utilizing a semiconductor photoresist composition according to some embodiments.

### DETAILED DESCRIPTION

Hereinafter, referring to the drawings, embodiments of present disclosure are described in more detail. In the following description of present disclosure, the functions or constructions known in the related art will not be described in order to clarify the present disclosure.

Throughout the disclosure, the same or similar configuration elements are designated by the same reference numerals. Also, because the size and thickness of each configuration shown in the drawing are arbitrarily shown for better understanding and ease of description, the present disclosure is not necessarily limited thereto.

In the drawings, the thickness of layers, films, panels, regions, and/or the like, may be enlarged for clarity. In the drawings, the thickness of a part of layers or regions, and/or the like, may be exaggerated for clarity. It will be understood that if (e.g., when) an element such as a layer, film, region, or substrate is referred to as being “on” another element, it can be directly on the other element or intervening elements may also be present.

As used herein, the term “substituted” refers to replacement of a hydrogen atom by deuterium, a halogen, a hydroxy group, a thiol group, a cyano group, a nitro group, a carbonyl group, —NRR′ (wherein, R and R′ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), —SiRR′R″ (wherein, R, R′, and R″ may each independently be hydrogen, a substituted or unsubstituted C1 to C30 saturated or unsaturated aliphatic hydrocarbon group, a substituted or unsubstituted C3 to C30 saturated or unsaturated alicyclic hydrocarbon group, or a substituted or unsubstituted C6 to C30 aromatic hydrocarbon group), a C1 to C30 alkyl group, a C1 to C10 haloalkyl group, a C1 to C10 alkylsilyl group, a C3 to C30 cycloalkyl group, a C6 to C30 aryl group, a C1 to C20 alkoxy group, a C1 to C20 sulfide group, or a (e.g., any suitable) combination thereof. The term “unsubstituted” refers to non-replacement of a hydrogen atom by another substituent and remaining as the hydrogen atom.

As used herein, if (e.g., when) a definition is not otherwise provided, the term “an alkyl group” refers to a linear or branched aliphatic hydrocarbon group. The alkyl group may be “a saturated alkyl group” without any double bond or triple bond.

The alkyl group may be a C1 to C10 alkyl group. For example, the alkyl group may be a C1 to C8 alkyl group, a C1 to C7 alkyl group, a C1 to C6 alkyl group, or a C1 to C5 alkyl group. For example, the C1 to C5 alkyl group may be a methyl group, an ethyl group, a propyl group, an isopropyl group, an n-butyl group, an isobutyl group, a sec-butyl group, a tert-butyl group, or a 2,2-dimethylpropyl group.

As used herein, if (e.g., when) a definition is not otherwise provided, the term “cycloalkyl group” refers to a monovalent cyclic aliphatic hydrocarbon group.

The cycloalkyl group may be a C3 to C10 cycloalkyl group, for example, a C3 to C8 cycloalkyl group, a C3 to C7 cycloalkyl group, or a C3 to C6 cycloalkyl group. For example, the cycloalkyl group may be a cyclopropyl group, a cyclobutyl group, a cyclopentyl group, or a cyclohexyl group, but the present disclosure is not limited thereto.

As used herein, the term “aryl group” refers to a cyclic substituent in which all atoms in the cyclic substituent have a p-orbital and these p-orbitals are conjugated, and may include a monocyclic or fused ring polycyclic functional group (i.e., rings sharing adjacent pairs of carbon atoms).

As used herein, unless otherwise defined, the term “alkenyl group” refers to an aliphatic unsaturated alkenyl group including at least one double bond as a linear or branched aliphatic hydrocarbon group.

As used herein, unless otherwise defined, the term “alkynyl group” refers to an aliphatic unsaturated alkynyl group including at least one triple bond as a linear or branched aliphatic hydrocarbon group.

In the chemical formulas described herein, t-Bu refers to a tert-butyl group.

Hereinafter, a semiconductor photoresist composition according to some embodiments is described.

The semiconductor photoresist composition according to some embodiments includes an organometallic compound represented by Chemical Formula 1 and a solvent.

(R¹)ₙ₁-M-[(X)—R²]ₘ₁ [Chemical Formula 1]

In Chemical Formula 1,
M may be a tetravalent metal, a pentavalent metal, or a hexavalent metal,
R¹ may be a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or L^{a}-O—R^{a} (wherein L^{a} may be a substituted or unsubstituted C1 to C20 alkylene group and R^{a} may be a substituted or unsubstituted C1 to C20 alkyl group),
R² may be a tert-butyl group, a benzoyl group, a pivaloyl group, an acetyl group, a tert-butyldiphenylsilyl group, a tert-butyldimethylsilyl group, an allyl group, a tetrahydropyranyl group, a methoxymethyl group, a benzyl ether group, a tert-butyl ether group, a p-toluenesulfonyl group, a 2-phenylethenyl group, a benzyl group, a trifluoromethyl group, a benzyl ester group, a tert-butyl ester group, a 9-fluorenylmethyl group, or a triphenylmethyl group,
X may be O-[L¹-O]ₙ₂ (wherein L¹ may be a substituted or unsubstituted C1 to C20 alkylene group, a substituted or unsubstituted C6 to C30 arylene group, or a (e.g., any suitable) combination thereof, and n2 may be an integer selected from 0 to 10), O—C(O)-[L²-C(O) O]ₙ₃ (wherein L² may be a substituted or unsubstituted C1 to C20 alkylene group, a substituted or unsubstituted C6 to C30 arylene group, or a (e.g., any suitable) combination thereof and n3 may be an integer selected from 0 to 10), N(R³)-[L³-N(R⁴)]ₙ₄ (wherein L³ may be a substituted or unsubstituted C1 to C20 alkylene group, a substituted or unsubstituted C6 to C30 arylene group, or a (e.g., any suitable) combination thereof, R³ and R⁴ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof, and n4 may be an integer selected from 0 to 10), N(R⁵)C(O)-[L⁴-N(R⁶)C(O)]ₙ₅ (wherein L⁴ may be a substituted or unsubstituted C1 to C20 alkylene group, a substituted or unsubstituted C6 to C30 arylene group, or a (e.g., any suitable) combination thereof, R⁵ and R⁶ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof, and n5 may be an integer selected from 0 to 10), or N(R⁷)C—N(R⁸)-[L⁵-N(R⁹)C—N(R¹⁰)]ₙ₆ (wherein L⁵ may be a substituted or unsubstituted C1 to C20 alkylene group, a substituted or unsubstituted C6 to C30 arylene group, or a (e.g., any suitable) combination thereof, R⁷ to R¹⁰ may each independently be hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or a (e.g., any suitable) combination thereof, and n6 may be an integer selected from 0 to 10),
n1 and m1 may each independently be an integers of 1 to 5, and

4≤n1+m1≤6.

The organometallic compound according to the present disclosure has a bulky structure due to substitution of R², and thus may have excellent or suitable storage stability and resistance to moisture.

In addition, during exposure, deprotection of R² occurs and condensation with surrounding or adjacent organometallic compound molecules through X occurs to form (or provide) a cluster, thereby improving sensitivity and resolution.

In some embodiments, M may be one selected from among Sn, Sb, I, Te, In, Ag, Ni, Bi, and Po.

In an embodiment, M may be Sn.

In some embodiments, R¹ may be a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or L^{a}-O—R^{a} (wherein L^{a} may be a substituted or unsubstituted C1 to C10 alkylene group and R^{a} may be a substituted or unsubstituted C1 to C10 alkyl group),
X may be O, O—C(O), N(R³) (wherein R³ may be hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a (e.g., any suitable) combination thereof), N(R⁵)C(O) (wherein R⁵ may be a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a (e.g., any suitable) combination thereof), or N(R⁷)C—N(R⁸) (wherein, R⁷ and R⁸ may each independently be a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or a (e.g., any suitable) combination thereof).

In some embodiments, R¹ may be a methyl group, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, a formyl group, an acetyl group, a propanoyl group, a butanoyl group, a pentanoyl group, an ethoxy group, a propoxy group, or a (e.g., any suitable) combination thereof.

In some embodiments, R³ to R¹⁰ may each independently be hydrogen, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, or a (e.g., any suitable) combination thereof.

The organometallic compound may be one selected from among compounds listed in Group 1.

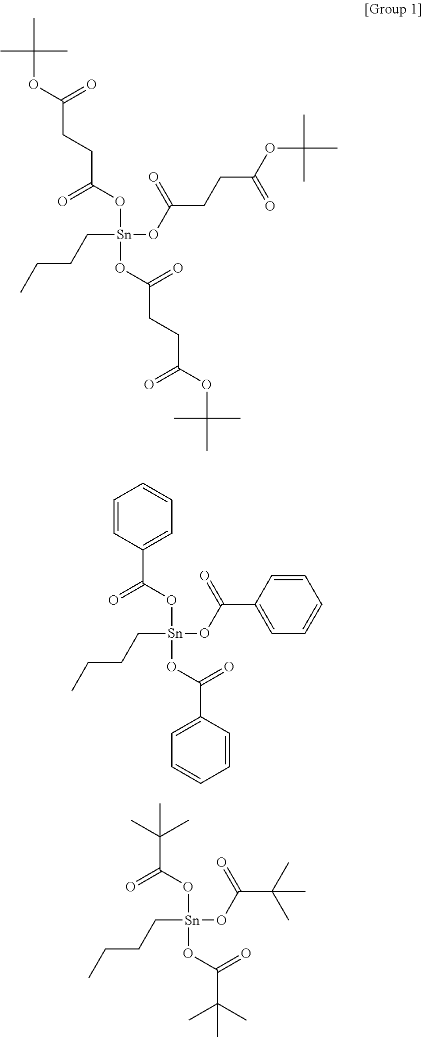

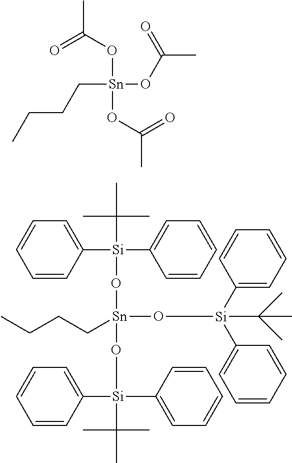

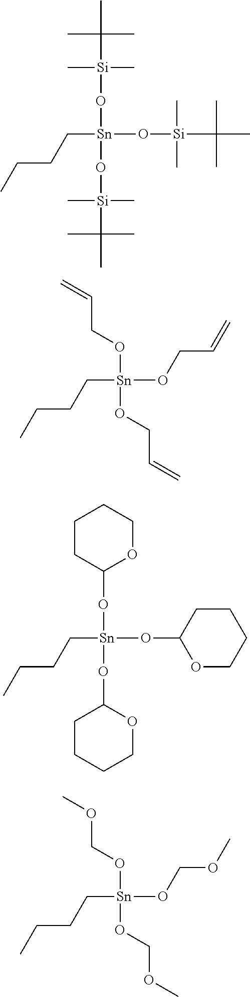

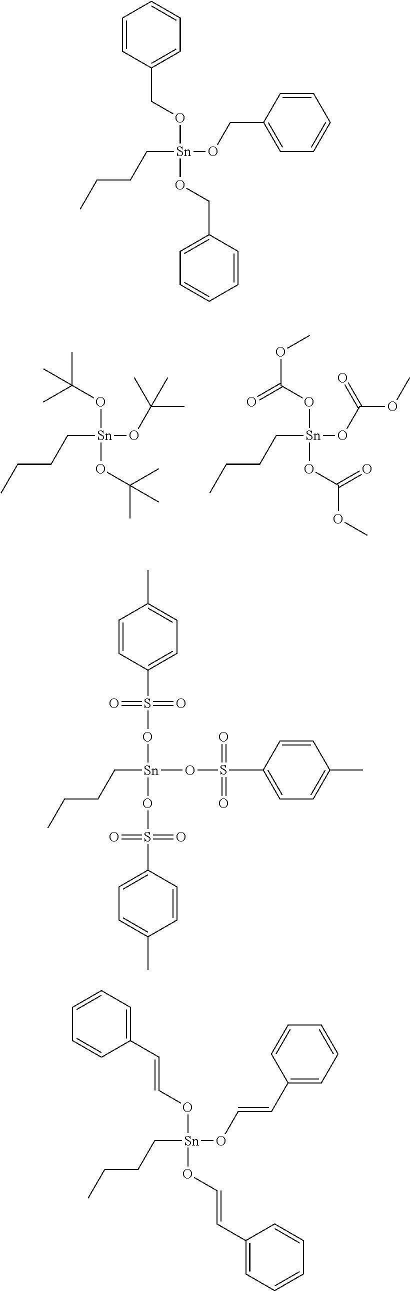

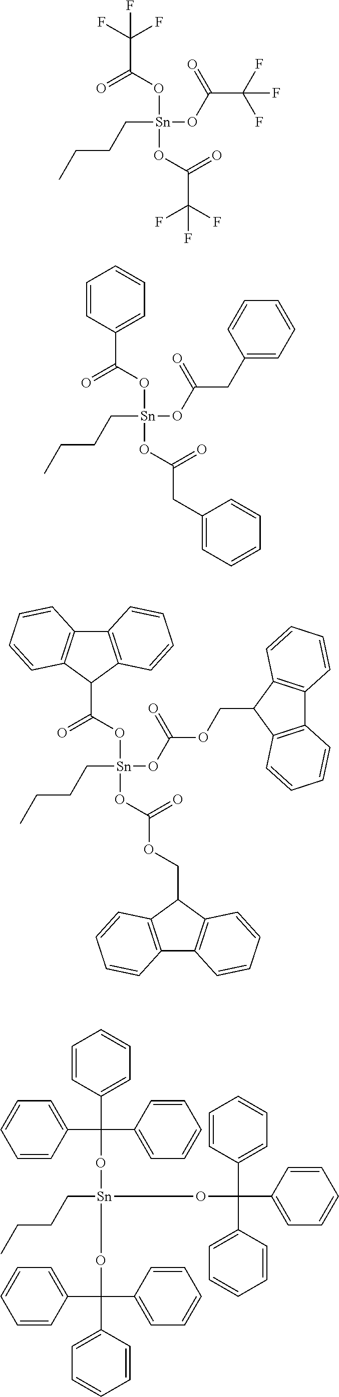 [SMILES: CCC[CH2][Sn]([O]C(=O)C(F)(F)F)([O]C(=O)C(F)(F)F)[O]C(=O)C(F)(F)F ; CCC[CH2][Sn]([O]C(=O)Cc1ccccc1)([O]C(=O)Cc1ccccc1)[O]C(=O)c1ccccc1 ; CCC[CH2][Sn]([O]C(=O)OCC1c2ccccc2-c2ccccc21)([O]C(=O)OCC1c2ccccc2-c2ccccc21)[O]C(=O)C1c2ccccc2-c2ccccc21 ; CCC[CH2][Sn]([O]C(c1ccccc1)(c1ccccc1)c1ccccc1)([O]C(c1ccccc1)(c1ccccc1)c1ccccc1)[O]C(c1ccccc1)(c1ccccc1)c1ccccc1]

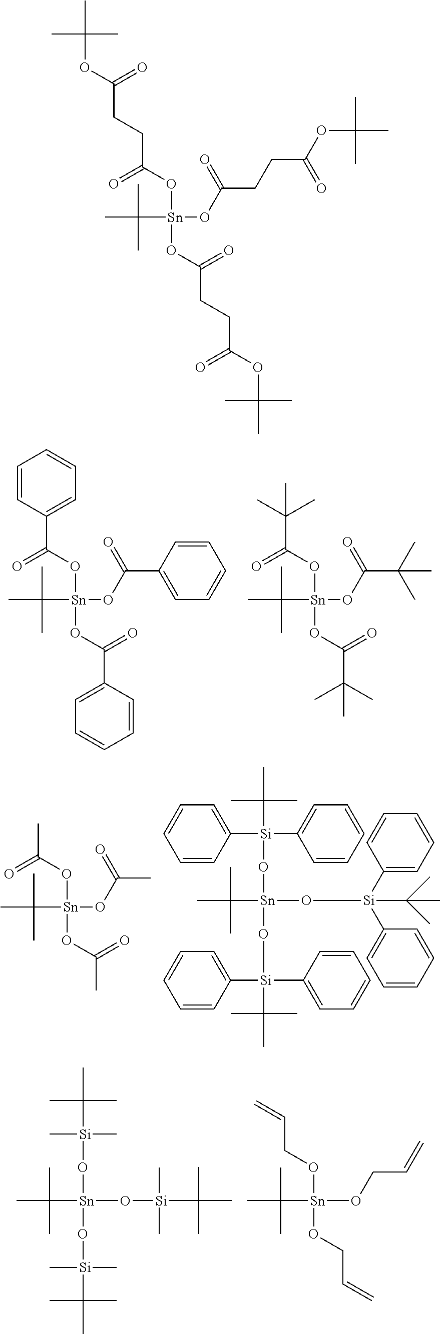

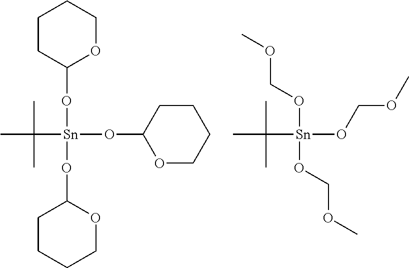

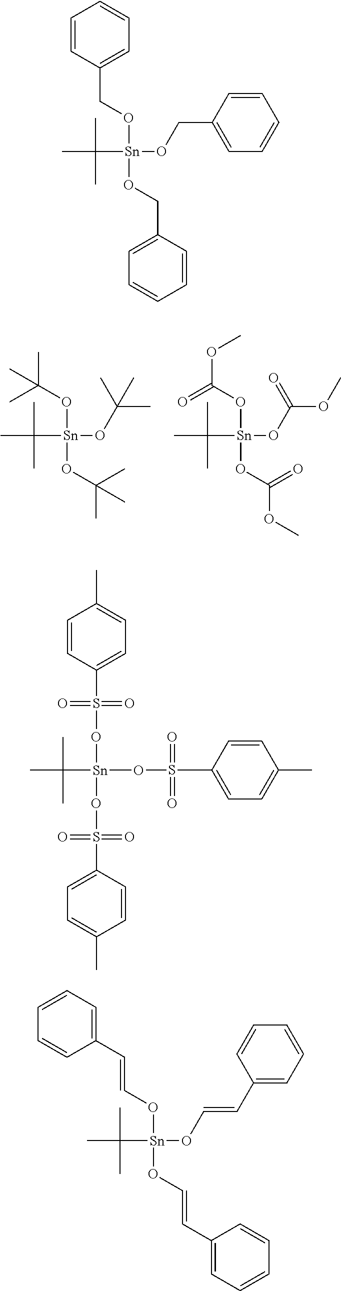

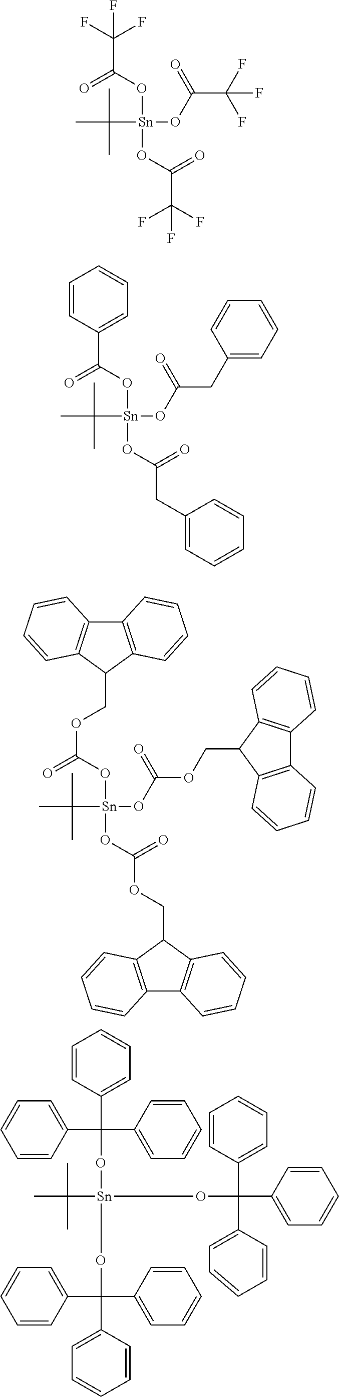

The organometallic compound suitably or strongly absorbs extreme ultraviolet light at about 13.5 nm and may have excellent or suitable sensitivity to relatively high-energy light.

The organometallic compound may be included in an amount of about 1 wt % to about 30 wt %, for example, about 1 wt % to about 25 wt %, about 1 wt % to about 20 wt %, about 1 wt % to about 15 wt %, about 1 wt % to about 10 wt %, or about 1 wt % to about 5 wt %, based on 100 wt % of the semiconductor photoresist composition, and the present disclosure is not limited thereto. If (e.g. when) the organometallic compound is included in the content (e.g., amount) within the above ranges, storage stability and etch resistance of the semiconductor photoresist composition are improved, and the resolution characteristics are improved.

Because the semiconductor photoresist composition according to some embodiments includes the aforementioned organometallic compound, a semiconductor photoresist composition having excellent or suitable sensitivity and stability may be provided.

The solvent of the semiconductor photoresist composition according to some embodiments may be an organic solvent, and may be for example, one or more aromatic compounds (e.g., xylene, toluene, and/or the like), alcohols (e.g., 4-methyl-2-pentenol, 4-methyl-2-propanol, 1-butanol, methanol, isopropyl alcohol, and/or 1-propanol), ethers (e.g., anisole, and/or tetrahydrofuran), esters (n-butyl acetate, propylene glycol monomethyl ether acetate, ethyl acetate, and/or ethyl lactate), ketones (e.g., methyl ethyl ketone, and/or 2-heptanone), or a (e.g., any suitable) mixture (e.g., combination) thereof, but the present disclosure is not limited thereto.

The semiconductor photoresist composition according to some embodiments may further include a resin in addition to the aforementioned organometallic compound and solvent.

The resin may be a phenolic resin including at least one aromatic moiety of Group 2.

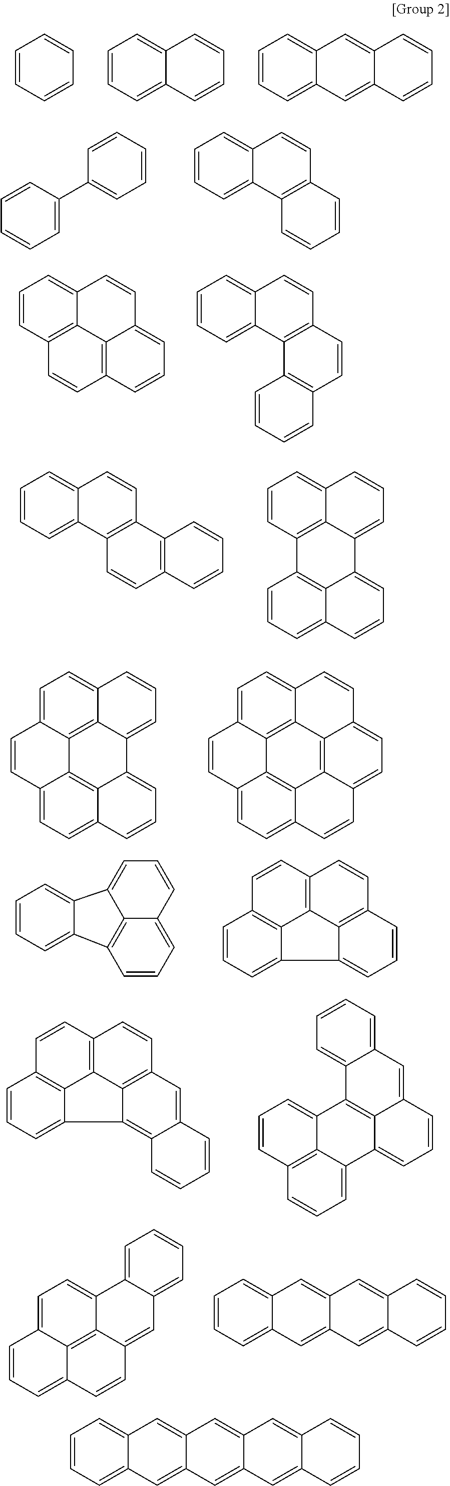

The resin may have a weight average molecular weight of about 500 to about 20,000.

The resin may be included in an amount of about 0.1 wt % to about 50 wt % based on the total amount of the semiconductor photoresist composition.

If (e.g., when) the resin is included in the above content (e.g., amount) range, it may have excellent or suitable etch resistance and heat resistance.

The semiconductor photoresist composition according to some embodiments may include (e.g., consist of) the aforementioned organometallic compound, solvent, and resin. However, the semiconductor photoresist composition according to some embodiments may further include one or more additives as needed. Examples of the additives may include (e.g., may be) a surfactant, a crosslinking agent, a leveling agent, an organic acid, a quencher, or a (e.g., any suitable) combination thereof.

The surfactant may include, for example, an alkyl benzene sulfonate salt, an alkyl pyridinium salt, polyethylene glycol, a quaternary ammonium salt, or a (e.g., any suitable) combination thereof, but the present disclosure is not limited thereto.

The crosslinking agent may include (e.g., may be), for example, a melamine-based crosslinking agent, a substituted urea-based crosslinking agent, an acryl-based crosslinking agent, an epoxy-based crosslinking agent, and/or a polymer-based crosslinking agent, but the present disclosure is not limited thereto. In some embodiments, the crosslinking agent may have at least two crosslinking forming (or providing) substituents, for example, a compound such as methoxymethylated glycoluril, butoxymethylated glycoluril, methoxymethylated melamine, butoxymethylated melamine, methoxymethylated benzoguanamine, butoxymethylated benzoguanamine, 4-hydroxybutyl acrylate, acrylic acid, urethane acrylate, acryl methacrylate, 1,4-butanediol diglycidyl ether, glycidol, diglycidyl 1,2-cyclohexane dicarboxylate, trimethylpropane triglycidyl ether, 1,3-bis(glycidoxypropyl)tetramethyldisiloxane, methoxymethylated urea, butoxymethylated urea, methoxymethylated thiourea, and/or the like.

The leveling agent may be utilized for improving coating flatness during printing and may be a commercially available suitable leveling agent.

The organic acid may include p-toluenesulfonic acid, benzenesulfonic acid, p-dodecylbenzenesulfonic acid, 1,4-naphthalenedisulfonic acid, methanesulfonic acid, a fluorinated sulfonium salt, malonic acid, citric acid, propionic acid, methacrylic acid, oxalic acid, lactic acid, glycolic acid, succinic acid, or a (e.g., any suitable) combination thereof, but the present disclosure is not limited thereto.

The quencher may include (e.g., may be) diphenyl (p-tolyl) amine, methyl diphenyl amine, triphenyl amine, phenylenediamine, naphthylamine, diaminonaphthalene, or a (e.g., any suitable) combination thereof.

An amount of the additives utilized in the photoresist composition may be controlled or selected depending on desired or suitable properties.

In one or more embodiments, the semiconductor photoresist composition may further include a silane coupling agent as an adherence enhancer in order to improve a close-contacting force with the substrate (e.g., in order to improve adherence of the semiconductor photoresist composition to the substrate). The silane coupling agent may be, for example, a silane compound including a carbon-carbon unsaturated bond such as vinyltrimethoxysilane, vinyl triethoxysilane, vinyl trichlorosilane, and/or vinyl tris (B-methoxyethoxy) silane; 3-methacryloxypropyltrimethoxysilane, 3-acryloxypropyltrimethoxysilane, p-styryl trimethoxysilane, 3-methacryloxypropylmethyldimethoxysilane, 3-methacryloxypropylmethyl diethoxysilane; trimethoxy [3-(phenylamino) propyl]silane, and/or the like, but the present disclosure is not limited thereto.

The semiconductor photoresist composition may be formed into a pattern having a relatively high aspect ratio without a collapse (e.g., without any collapsed portions). Accordingly, in order to form (or provide) a fine pattern having a width of, for example, about 5 nm to about 100 nm, about 5 nm to about 80 nm, about 5 nm to about 70 nm, about 5 nm to about 50 nm, about 5 nm to about 40 nm, about 5 nm to about 30 nm, about 5 nm to about 20 nm, or about 5 nm to about 10 nm, the semiconductor photoresist composition may be utilized for a photoresist process utilizing light with a wavelength in a range of about 5 nm to about 150 nm, for example, about 5 nm to about 100 nm, about 5 nm to about 80 nm, about 5 nm to about 50 nm, about 5 nm to about 30 nm, or about 5 nm to about 20 nm. Accordingly, the semiconductor photoresist composition according to some embodiments may be utilized to realize extreme ultraviolet lithography utilizing an EUV light source with a wavelength of about 13.5 nm.

According to some embodiments, a method of forming (or providing) patterns utilizing the aforementioned semiconductor photoresist composition is provided. For example, the manufactured pattern may be a photoresist pattern.

The method of forming (or providing) patterns according to some embodiments includes forming (or providing) an etching-objective layer on a substrate, coating the semiconductor photoresist composition on the etching-objective layer to form (or provide) a photoresist layer, patterning the photoresist layer to form (or provide) a photoresist pattern, and etching the etching-objective layer utilizing the photoresist pattern as an etching mask.

Hereinafter, a method of forming (or providing) patterns utilizing the semiconductor photoresist composition is described by referring to FIGS. 1 to 5. FIGS. 1 to 5 are cross-sectional views for explaining a method of forming (or providing) patterns utilizing a semiconductor photoresist composition according to some embodiments. Here, unless otherwise defined, the listing of steps, tasks, or acts in a particular order should not necessarily means that the invention or claims require that particular order. That is, the general rule that unless the steps, tasks, or acts of a method (e.g., a method claim) actually recite an order, the steps, tasks, or acts should not be construed to require one.

Referring to FIG. 1, an object to be etched is prepared. The object to be etched may be a thin film 102 formed on a semiconductor substrate 100. Hereinafter, the object to be etched is limited to the thin film 102. A whole surface of the thin film 102 is washed to remove impurities and/or the like remaining thereon. The thin film 102 may be, for example, a silicon nitride layer, a polysilicon layer, or a silicon oxide layer.

Subsequently, the resist underlayer composition for providing a resist underlayer 104 is spin-coated on the surface of the washed thin film 102. However, the present disclosure is not limited thereto, and any suitable coating methods, for example, a spray coating, a dip coating, a knife edge coating, a printing method (for example, inkjet printing and screen printing), and/or the like may be utilized.

In some embodiments, the coating process for providing the resist underlayer may not be provided, and hereinafter, a process including a coating process for providing the resist underlayer is described.

Then, the coated composition is dried and baked to form (or provide) a resist underlayer 104 on the thin film 102. The baking may be performed at about 100° C. to about 500° C., for example, about 100° C. to about 300° C.

The resist underlayer 104 is formed between the substrate 100 and a photoresist layer 106 and thus may prevent or reduce non-uniformity and prevent or reduce unintended pattern-forming of a photoresist if (e.g., when) a ray reflected from on the interface between the substrate 100 and the photoresist layer 106 or a hard mask between layers is scattered into an unintended photoresist region.

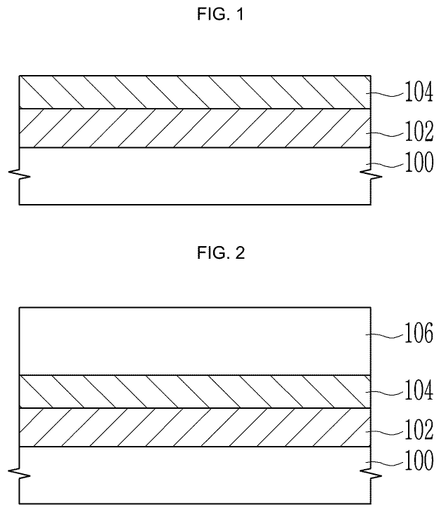

Referring to FIG. 2, the photoresist layer 106 is formed by coating the semiconductor photoresist composition on the resist underlayer 104. The photoresist layer 106 is obtained by coating the aforementioned semiconductor photoresist composition on the thin film 102 formed on the substrate 100 and then, curing it through a heat treatment.

In some embodiments, the formation of a pattern by utilizing the semiconductor photoresist composition may include coating the semiconductor photoresist composition on the substrate 100 having the thin film 102 thereon through spin coating, slit coating, inkjet printing, and/or the like and then, drying it to form (or provide) the photoresist layer 106.

The semiconductor photoresist composition has already been illustrated in more detail and will not be illustrated again.

Subsequently, the substrate 100 having the photoresist layer 106 thereon is subjected to a first baking process. The first baking process may be performed at about 80° C. to about 120° C.

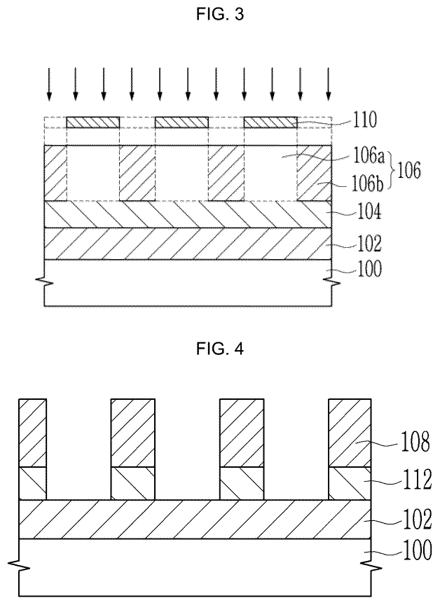

Referring to FIG. 3, the photoresist layer 106 may be selectively exposed utilizing a patterned mask 110.

For example, the exposure may utilize an activation radiation with light having a relatively high energy wavelength such as EUV (extreme ultraviolet; a wavelength of about 13.5 nm), an E-Beam (an electron beam), and/or the like as well as light having a relatively short wavelength such as an i-line (a wavelength of about 365 nm), a KrF excimer laser (a wavelength of about 248 nm), an ArF excimer laser (a wavelength of about 193 nm), and/or the like.

Light for the exposure according to some embodiments may have a relatively short wavelength (in a range of about 5 nm to about 150 nm) and a relatively high energy wavelength, for example, EUV (extreme ultraviolet; a wavelength of 13.5 nm), an E-Beam (an electron beam), and/or the like.

The exposed region 106b of the photoresist layer 106 has a different solubility from the unexposed region 106a of the photoresist layer 106 by forming (or providing) a polymer through a crosslinking reaction such as condensation between organometallic compounds.

Subsequently, the substrate 100 is subjected to a second baking process. The second baking process may be performed at a temperature of about 90° C. to about 200° C. The exposed region 106b of the photoresist layer 106 becomes indissoluble (e.g., easily indissoluble) by a developer due to the second baking process.

In FIG. 4, the unexposed region 106a of the photoresist layer is dissolved and removed utilizing the developer to form (or provide) a photoresist pattern 108. For example, the unexposed region 106a of the photoresist layer is dissolved and removed by utilizing an organic solvent such as 2-heptanone and/or the like to complete the photoresist pattern 108 corresponding to the negative tone image.

As described above, a developer utilized in a method of forming (or providing) patterns according to some embodiments may be an organic solvent. The organic solvent utilized in the method of forming (or providing) patterns according to some embodiments may be, for example, one or more ketones such as methylethylketone, acetone, cyclohexanone, 2-heptanone, and/or the like, alcohols such as 4-methyl-2-propanol, 1-butanol, isopropanol, 1-propanol, methanol, and/or the like, esters such as propylene glycol monomethyl ether acetate, ethyl acetate, ethyl lactate, n-butyl acetate, butyrolactone, and/or the like, aromatic compounds such as benzene, xylene, toluene, and/or the like, and/or a (e.g., any suitable) combination thereof.

However, the photoresist pattern according to some embodiments is not necessarily limited to the negative tone image but may be formed to have a positive tone image. Herein, a developer utilized for forming (or providing) the positive tone image may be a quaternary ammonium hydroxide composition such as tetraethylammonium hydroxide, tetrapropylammonium hydroxide, tetrabutylammonium hydroxide, and/or a (e.g., any suitable) combination thereof.

As described above, exposure to light having a relatively high energy such as EUV (extreme ultraviolet; a wavelength of 13.5 nm), an E-Beam (an electron beam), and/or the like as well as light having a relatively short wavelength such as i-line (wavelength of about 365 nm), KrF excimer laser (wavelength of about 248 nm), ArF excimer laser (wavelength of about 193 nm), and/or the like may provide a photoresist pattern 108 having a width of a thickness (e.g., width) of about 5 nm to about 100 nm. For example, the photoresist pattern 108 may have a width of a thickness (e.g., width) of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, about 5 nm to about 20 nm, or about 5 nm to about 10 nm.

Also, the photoresist pattern 108 may have a pitch with a half-pitch of less than or equal to about 50 nm, for example, less than or equal to about 40 nm, less than or equal to about 30 nm, less than or equal to about 20 nm, or less than or equal to about 10 nm, and a line width roughness of less than or equal to about 5 nm, less than or equal to about 3 nm, less than or equal to about 2 nm, or less than or equal to about 1 nm.

Subsequently, the photoresist pattern 108 is utilized as an etching mask to etch the resist underlayer 104. Through this etching process, an organic layer pattern 112 is formed. The organic layer pattern 112 also may have a width corresponding to that of the photoresist pattern 108.

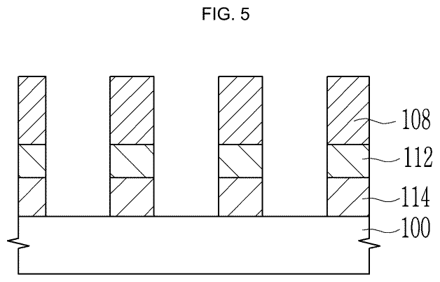

Referring to FIG. 5, the exposed thin film 102 is etched by applying the photoresist pattern 108 as an etching mask. As a result, the thin film is formed as a thin film pattern 114.

The etching of the thin film 102 may be, for example, dry etching utilizing an etching gas and the etching gas may be, for example, CHF₃, CF₄, Cl₂, BCl₃ or a mixed gas thereof.

In the exposure process, the thin film pattern 114 formed by utilizing the photoresist pattern 108 (formed through the exposure process performed by utilizing an EUV light source) may have a width corresponding to that of the photoresist pattern 108. For example, the thin film pattern 114 may have a width of 5 nm to 100 nm, which is equal or substantially equal to that of the photoresist pattern 108. For example, the thin film pattern 114 formed by utilizing the photoresist pattern 108 (formed through the exposure process performed by utilizing an EUV light source) may have a width of about 5 nm to about 90 nm, about 5 nm to about 80 nm, about 5 nm to about 70 nm, about 5 nm to about 60 nm, about 5 nm to about 50 nm, about 5 nm to about 40 nm, about 5 nm to about 30 nm, or about 5 nm to about 20 nm, and in an embodiment, a width of less than or equal to about 20 nm, the same or substantially the same as that of the photoresist pattern 108.

Hereinafter, the present disclosure will be described in more detail through examples of the preparation of the aforementioned semiconductor photoresist composition. However, the present disclosure is technically not restricted by the following examples.

### Synthesis of Organometallic Compounds

### Synthesis Example 1

25 mL of propionic acid was slowly added dropwise to tert-butyltriphenyltin compound (10 g, 25.6 mmol) at room temperature, and then heated and refluxed at 110° C. for 24 hours. Afterwards, the temperature was lowered to room temperature and propionic acid was vacuum distilled to obtain a compound represented by Chemical Formula 2.

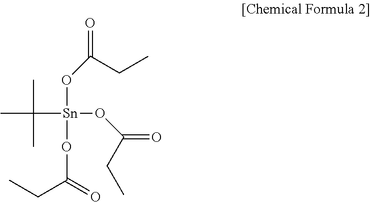 [SMILES: CCC(=O)[O][Sn]([O]C(=O)CC)([O]C(=O)CC)[C](C)(C)C]

### Synthesis Example 2

An equivalent amount of mono-tert-butyl succinate was slowly added dropwise to the compound represented by Chemical Formula 2 obtained in Synthesis Example 1, and then stirred at room temperature for 24 hours to obtain a compound represented by Chemical Formula 3.

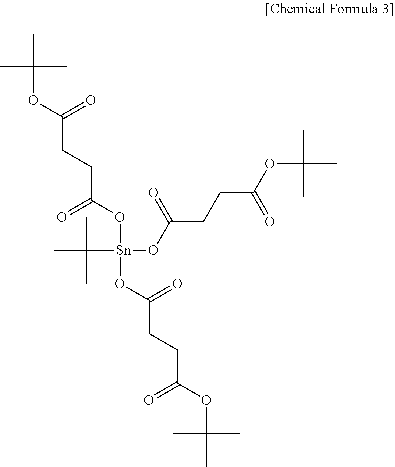 [SMILES: CC(C)(C)OC(=O)CCC(=O)[O][Sn]([O]C(=O)CCC(=O)OC(C)(C)C)([O]C(=O)CCC(=O)OC(C)(C)C)[C](C)(C)C]

### Synthesis Example 3

The synthesis was performed in substantially the same manner as in Synthesis Example 2 except that mono-tert-butylmalonate was utilized instead of mono-tert-butyl succinate to obtain a compound represented by Chemical Formula 4.

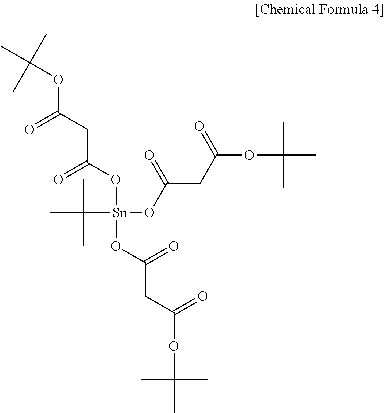 [SMILES: CC(C)(C)OC(=O)CC(=O)[O][Sn]([O]C(=O)CC(=O)OC(C)(C)C)([O]C(=O)CC(=O)OC(C)(C)C)[C](C)(C)C]

### Synthesis Example 4

The synthesis was performed in substantially the same manner as in Synthesis Example 2 except that 3-((tert-butyldimethylsilyl)oxy)-propanol was utilized instead of mono-tert-butyl succinate to obtain a compound represented by Chemical Formula 5.

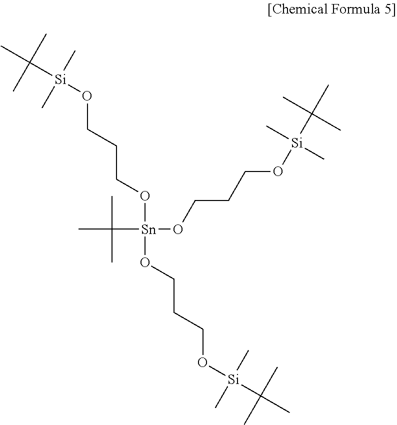 [SMILES: CC(C)(C)[Si](C)(C)OCCC[O][Sn]([O]CCCO[Si](C)(C)C(C)(C)C)([O]CCCO[Si](C)(C)C(C)(C)C)[C](C)(C)C]

### Synthesis Example 5

The synthesis was performed in substantially the same manner as in Synthesis Example 2 except that n-butyltriphenyltin compound was utilized instead of tert-butyltriphenyltin compound to obtain a compound represented by Chemical Formula 6.

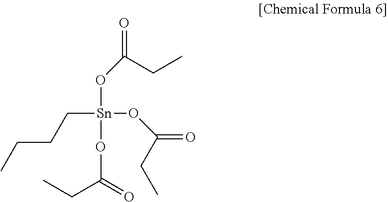 [SMILES: CCC[CH2][Sn]([O]C(=O)CC)([O]C(=O)CC)[O]C(=O)CC]

### Preparation of Semiconductor Photoresist Compositions

### Examples 1 to 3 and Comparative Examples 1 and 2

The compounds represented by Chemical Formulas 2 to 6 obtained in Synthesis Examples 1 to 5 were respectively dissolved in 4-methyl-2-pentanol at 3 wt %, and filtered through a 0.1 μm PTFE syringe filter to prepare a photoresist composition.

A 4-inch diameter circular silicon wafer with a native-oxide surface was utilized as a substrate for thin film deposition. Before deposition of the resist thin film, the wafer was treated in a UV ozone cleaning system for 10 minutes, the resist composition was then spin-coated on the wafer at 1500 rpm for 30 seconds, and baked at 120° C. for 120 seconds to form (or provide) a resist thin film. Afterwards, the thickness of the resist thin film (after coating and baking) was measured utilizing ellipsometry, wherein the thickness was 20 nm for each of Examples 1 to 3 and Comparative Examples 1 to 2.

### Evaluation 1: Sensitivity Evaluation

The substrate, on which the resist thin film was deposited, was exposed to an E-beam with an acceleration voltage of 100 kV to form (or provide) nanowires of 40 nm half-pitch. The irradiated substrate was exposed to 40° C. for 30 seconds, then dipped into a petri dish containing 2-heptanone for 60 seconds, taken out, washed with the same solvent for about 10 seconds, and finally baked at 150° C. To confirm a pattern performance of a patterning substrate, the critical dimension (CD) size of the formed line was measured utilizing field emission scanning electron microscopy (FE-SEM) images. Sensitivity was indicated as follow:
⊚ if the CD size is more than or equal to 40 nm,
o if the CD size is more than or equal to 35 nm, and
Δ if the CD size is less than or equal to 35 nm at 1000 Uc/cm² energy.

### Evaluation 2: Evaluation of Moisture Stability

To analyze the degree to which changes occurred due to moisture, 10 wt % of a respective tin compound (the organometallic compound) utilized in Examples 1 to 3 and Comparative Examples 1 to 2 was dissolved in 1-methoxy-2-propyl acetate solvent containing 1 wt % of water. Afterwards, ¹¹⁹Sn NMR measurement of the solution was performed. The results were evaluated according to the following criteria and are shown in Table 1.
※ Evaluation criteria:
⊚: No change in NMR peak.
o: 1 to 29% change in total integral value
Δ: 30 to 89% change in total integral value
X: change of more than or equal to 90% of the total integral value

### Evaluation 3: Evaluation of Storage Stability

The storage stability of the organometallic compounds utilized in Examples 1 to 3 and Comparative Examples 1 and 2 was evaluated based on the following criteria, and the results are shown in Table 1.

### [Storage Stability]

After the semiconductor photoresist compositions according to Examples 1 to 3 and Comparative Examples 1 and 2 were left at room temperature (20+5° C.) for a certain period of time, the degree of precipitation was visually observed, and evaluated according to the storage standards.
※ Evaluation criteria
   ⊚: can be stored for more than or equal to 4 months
   o: can be stored for more than or equal to 3 months and less than 4 months
   Δ: can be stored for more than or equal to 1 month and less than 3 months
   X: can be stored for less than 2 weeks

TABLE 1

| | Organometallic | Storage | Moisture | |
|---|---|---|---|---|
| | compound | stability | stability | Sensitivity |
| Example 1 | Chemical | ⊚ | ⊚ | ⊚ |
| | Formula 3 | | | |
| Example 2 | Chemical | ◯ | ◯ | ⊚ |
| | Formula 4 | | | |
| Example 3 | Chemical | ◯ | ⊚ | ◯ |
| | Formula 5 | | | |
| Comparative | Chemical | Δ | Δ | Δ |
| Example 1 | Formula 2 | | | |
| Comparative | Chemical | Δ | X | Δ |
| Example 2 | Formula 6 | | | |

From the results in Table 1, it can be seen that the semiconductor photoresist compositions according to the examples exhibit excellent or suitable sensitivity and significantly improved storage stability compared to those according to the comparative examples.

The use of “may” when describing embodiments of the inventive concept refers to “one or more embodiments of the inventive concept.”

As used herein, the term “about,” and similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Also, any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

While this disclosure has been described in connection with what is presently considered to be practical example embodiments, it is to be understood that present disclosure is not limited to the disclosed embodiments, but, on the contrary, is intended to cover various modifications and equivalent arrangements included within the spirit and scope of the appended claims, and equivalents thereof.

<Reference Numerals >

| | |
|---|---|
| 100: substrate | 102: thin film |
| 104: resist underlayer | 106: photoresist layer |
| 106a: unexposed region | 106b: exposed region |
| 108: photoresist pattern | 112: organic layer pattern |
| 110: patterned mask | 114: thin film pattern |

What is claimed is:

1. A semiconductor photoresist composition, comprising:
an organometallic compound represented by Chemical Formula 1; and
a solvent:
(R¹)ₙ₁-M-[(X)—R²]ₘ₁ [Chemical Formula 1]
wherein, in Chemical Formula 1,
M is a tetravalent metal, a pentavalent metal, or a hexavalent metal,
R¹ is a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, a substituted or unsubstituted C6 to C30 aryl group, or L^{a}-O—R^{a}, wherein L^{a} is a substituted or unsubstituted C1 to C20 alkylene group and R^{a} is a substituted or unsubstituted C1 to C20 alkyl group,
R² is a tert-butyl group, a benzoyl group, a pivaloyl group, an acetyl group, a tert-butyldiphenylsilyl group, a tert-butyldimethylsilyl group, an allyl group, a tetrahydropyranyl group, a methoxymethyl group, a benzyl ether group, a tert-butyl ether group, a p-toluenesulfonyl group, a 2-phenylethenyl group, a benzyl group, a trifluoromethyl group, a benzyl ester group, a tert-butyl ester group, a 9-fluorenylmethyl group, or a triphenylmethyl group,
X is O-[L¹-O]ₙ₂, O—C(O)-[L²-C(O)O]ₙ₃, N(R³)-[L³-N(R⁴)]ₙ₄, N(R⁵)C(O)-[L⁴-N(R⁶)C(O)]ₙ₅, or N(R⁷)C—N(R⁸)-[L⁵-N(R⁹)C—N(R¹⁰)]ₙ₆,
L¹ being a substituted or unsubstituted C1 to C20 alkylene group, or a substituted or unsubstituted C6 to C30 arylene group, and n2 being an integer selected from 0 to 10,
L² being a substituted or unsubstituted C1 to C20 alkylene group, or a substituted or unsubstituted C6 to C30 arylene group, and n3 being an integer selected from 0 to 10,
L³ being a substituted or unsubstituted C1 to C20 alkylene group, or a substituted or unsubstituted C6 to C30 arylene group, R³ and R⁴ being each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, or a substituted or unsubstituted C6 to C30 aryl group, and n4 being an integer selected from 0 to 10,
L⁴ being a substituted or unsubstituted C1 to C20 alkylene group, or a substituted or unsubstituted C6 to C30 arylene group, R⁵ and R⁶ being each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, or a substituted or unsubstituted C6 to C30 aryl group, and n5 being an integer selected from 0 to 10,
L⁵ being a substituted or unsubstituted C1 to C20 alkylene group, or a substituted or unsubstituted C6 to C30 arylene group, R⁷ to R¹⁰ being each independently hydrogen, a substituted or unsubstituted C1 to C20 alkyl group, a substituted or unsubstituted C3 to C20 cycloalkyl group, a substituted or unsubstituted C2 to C20 alkenyl group, a substituted or unsubstituted C2 to C20 alkynyl group, or a substituted or unsubstituted C6 to C30 aryl group, and n6 being an integer selected from 0 to 10,
n1 and m1 being each independently an integer selected from 1 to 5, and
4≤n1+m1≤6.

2. The semiconductor photoresist composition as claimed in claim 1, wherein M is Sn, Sb, I, Te, In, Ag, Ni, Bi, or Po.

3. The semiconductor photoresist composition as claimed in claim 1, wherein M is Sn.

4. The semiconductor photoresist composition as claimed in claim 1, wherein
R¹ is a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, a substituted or unsubstituted C6 to C20 aryl group, or L^{a}-O—R^{a}, wherein L^{a} is a substituted or unsubstituted C1 to C10 alkylene group and R^{a} is a substituted or unsubstituted C1 to C10 alkyl group, and
X is O, O—C(O), N(R³), N(R⁵)C(O), or N(R⁷)C—N(R⁸),
R³ being hydrogen, a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, or a substituted or unsubstituted C6 to C20 aryl group,
R⁵ being a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, or a substituted or unsubstituted C6 to C20 aryl group, and
R⁷ and R⁸ being each independently a substituted or unsubstituted C1 to C10 alkyl group, a substituted or unsubstituted C3 to C10 cycloalkyl group, a substituted or unsubstituted C2 to C10 alkenyl group, a substituted or unsubstituted C2 to C10 alkynyl group, or a substituted or unsubstituted C6 to C20 aryl group.

5. The semiconductor photoresist composition as claimed in claim 1, wherein R¹ is a methyl group, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, a benzyl group, a formyl group, an acetyl group, a propanoyl group, a butanoyl group, a pentanoyl group, an ethoxy group, or a propoxy group.

6. The semiconductor photoresist composition as claimed in claim 1, wherein R³ to R¹⁰ are each independently hydrogen, an ethyl group, a propyl group, a butyl group, an isopropyl group, a tert-butyl group, a 2,2-dimethylpropyl group, a cyclopropyl group, a cyclobutyl group, a cyclopentyl group, a cyclohexyl group, an ethenyl group, a propenyl group, a butenyl group, an ethynyl group, a propynyl group, a butynyl group, a phenyl group, a tolyl group, a xylene group, or a benzyl group.

7. The semiconductor photoresist composition as claimed in claim 1, wherein the organometallic compound is one selected from among compounds listed in Group 1:

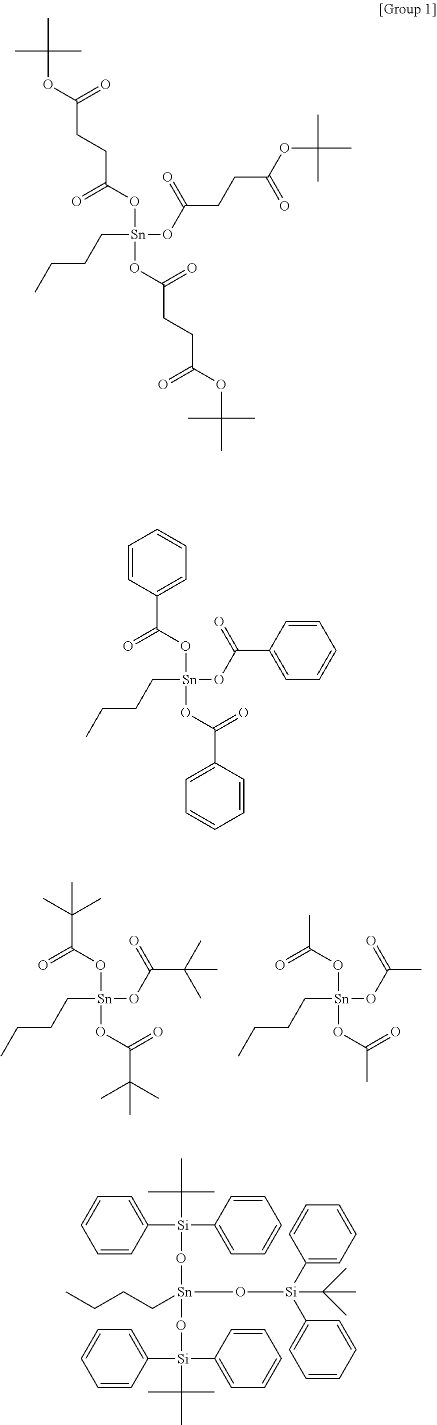

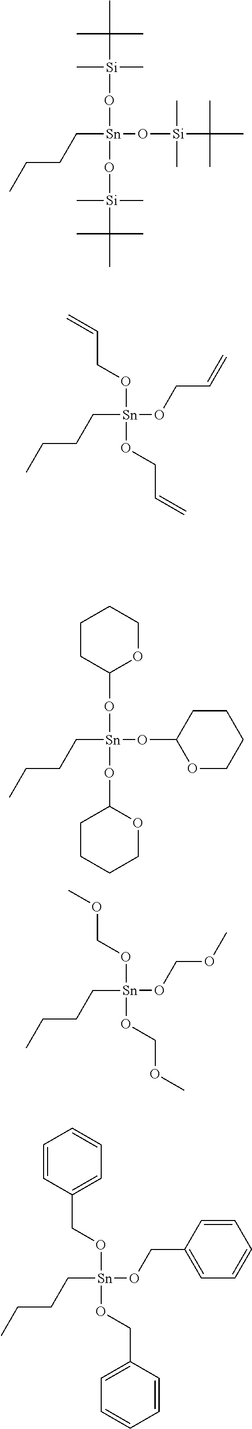

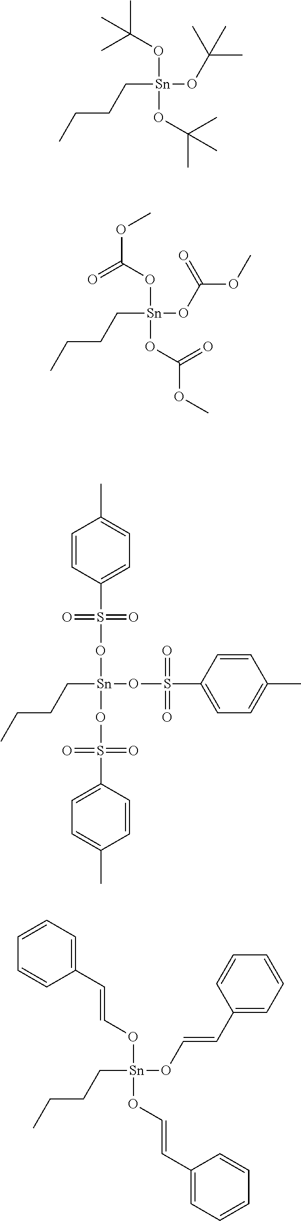

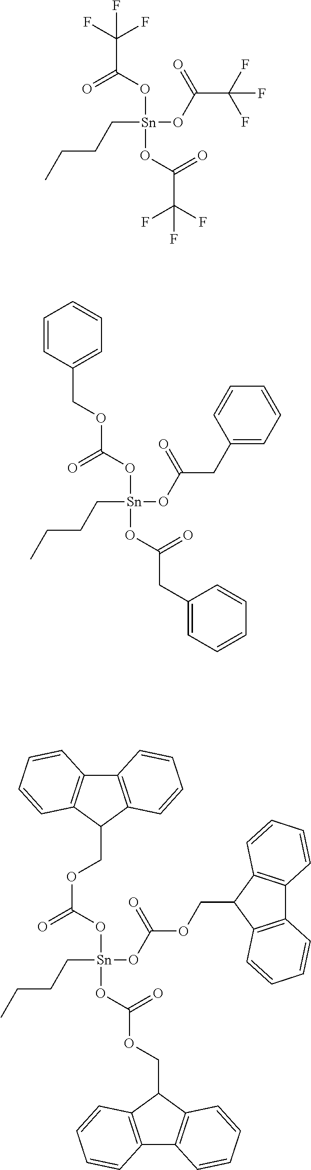 [SMILES: CCC[CH2][Sn]([O]C(=O)C(F)(F)F)([O]C(=O)C(F)(F)F)[O]C(=O)C(F)(F)F ; CCC[CH2][Sn]([O]C(=O)Cc1ccccc1)([O]C(=O)Cc1ccccc1)[O]C(=O)OCc1ccccc1 ; CCC[CH2][Sn]([O]C(=O)OCC1c2ccccc2-c2ccccc21)([O]C(=O)OCC1c2ccccc2-c2ccccc21)[O]C(=O)OCC1c2ccccc2-c2ccccc21]

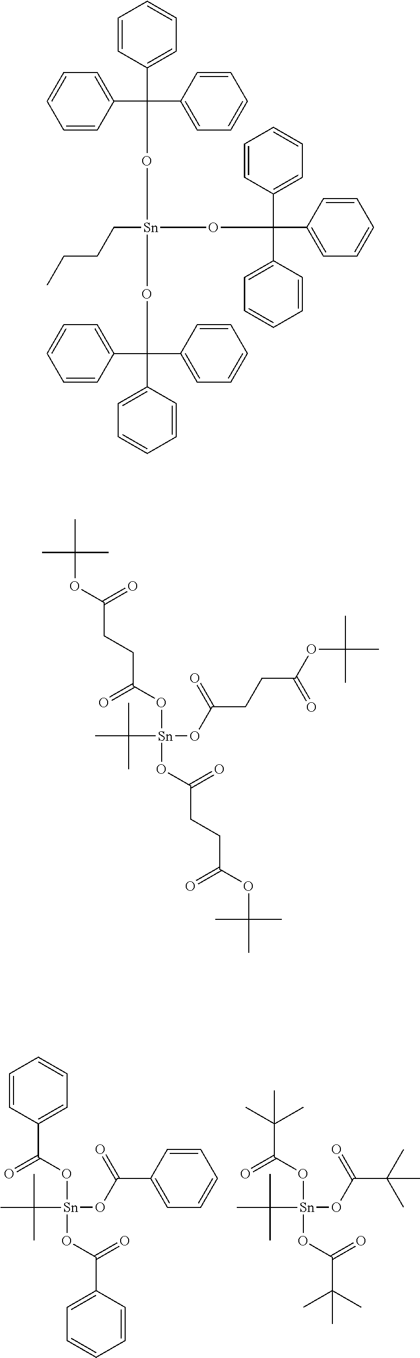

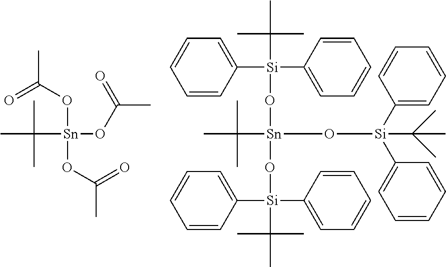

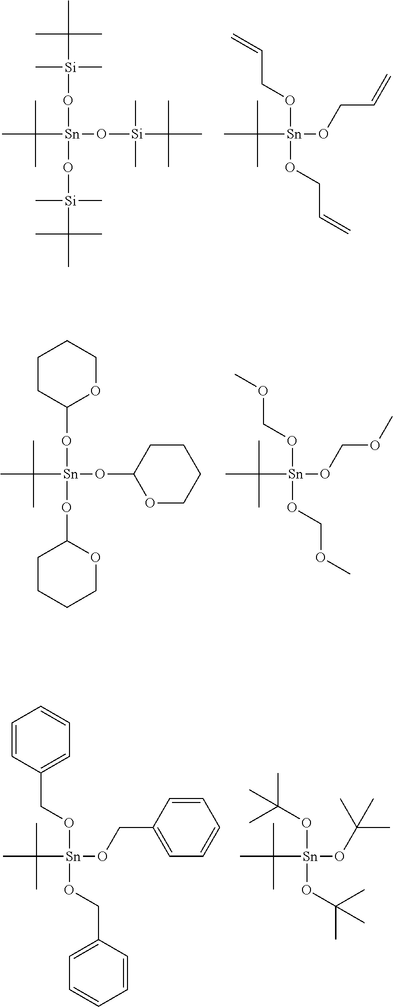

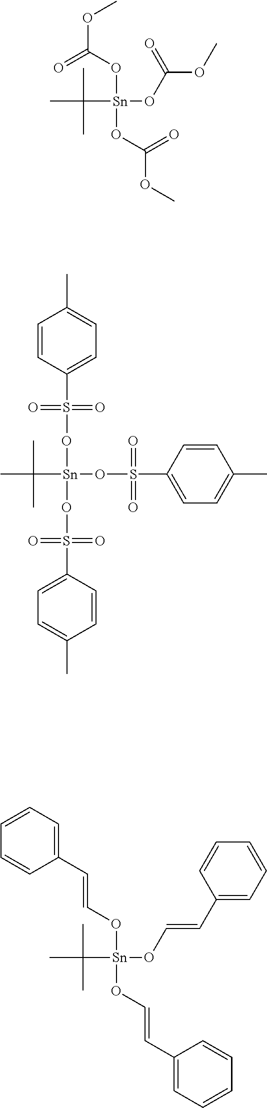

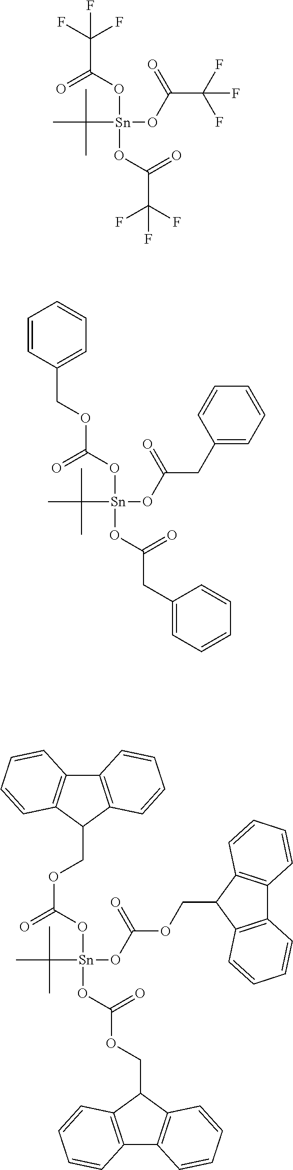 [SMILES: C[C](C)(C)[Sn]([O]C(=O)C(F)(F)F)([O]C(=O)C(F)(F)F)[O]C(=O)C(F)(F)F ; C[C](C)(C)[Sn]([O]C(=O)Cc1ccccc1)([O]C(=O)Cc1ccccc1)[O]C(=O)OCc1ccccc1 ; C[C](C)(C)[Sn]([O]C(=O)OCC1c2ccccc2-c2ccccc21)([O]C(=O)OCC1c2ccccc2-c2ccccc21)[O]C(=O)OCC1c2ccccc2-c2ccccc21]

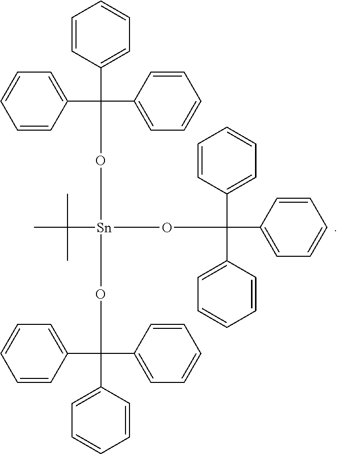 [SMILES: C[C](C)(C)[Sn]([O]C(c1ccccc1)(c1ccccc1)c1ccccc1)([O]C(c1ccccc1)(c1ccccc1)c1ccccc1)[O]C(c1ccccc1)(c1ccccc1)c1ccccc1]

8. The semiconductor photoresist composition as claimed in claim 1, wherein the organometallic compound is about 1 wt % to about 30 wt % in amount based on 100 wt % of the semiconductor photoresist composition.

9. The semiconductor photoresist composition as claimed in claim 1, further comprising a surfactant, a crosslinking agent, a leveling agent, an organic acid, a quencher, or a combination thereof.

10. A method of forming patterns, the method comprising:
forming an etching-objective layer on a substrate;
coating the semiconductor photoresist composition as claimed in claim 1 on the etching-objective layer to form a photoresist layer;
patterning the photoresist layer to form a photoresist pattern; and
etching the etching-objective layer utilizing the photoresist pattern as an etching mask.

11. The method as claimed in claim 10, wherein the photoresist pattern is formed utilizing light with a wavelength of about 5 nm to about 150 nm.

12. The method as claimed in claim 10, further comprising providing a resist underlayer between the substrate and the photoresist layer.

13. The method as claimed in claim 10, wherein the photoresist pattern has a width of about 5 nanometers (nm) to about 100 nm.
